(19) United States
(12) Patent Application Publication
(10) Pub. No.: US 2025/0133786 A1
(43) Pub. Date: Apr. 24, 2025

(54) ADDITIVE APPROACHES TO MODIFYING WAFER GEOMETRY

(71) Applicant: Micron Technology, Inc., Boise, ID (US)

(72) Inventor: Kunal R. Parekh, Boise, ID (US)

(21) Appl. No.: 18/914,918

(22) Filed: Oct. 14, 2024

Related U.S. Application Data
(60) Provisional application No. 63/545,509, filed on Oct. 24, 2023.

(51) Int. Cl. H01L 29/06; H01L 21/02; H01L 21/3105

(52) U.S. Cl. CPC H10D 62/117; H01L 21/02288; H01L 21/31053

(57) ABSTRACT

A method for modifying a geometry of a wafer comprises measuring a local geometry for each of a plurality edge locations of the wafer, determining, based on the measured local geometry, an amount of additional material for each of the plurality of locations of the wafer calculated to provide a desired wafer-level geometry for the wafer, and dispensing, from a printing nozzle, the determined amount of additional material at each of the plurality of locations of the wafer to provide the wafer with the desired wafer-level geometry.

### CROSS-REFERENCE TO RELATED APPLICATION(S)

The present application claims priority to U.S. Provisional Patent Application No. 63/545,509, filed Oct. 24, 2023, the disclosure of which is incorporated herein by reference in its entirety.

### TECHNICAL FIELD

The present disclosure generally relates to semiconductor device assemblies, and more particularly relates to additive approaches to modifying wafer geometry.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

For efficiency of large-volume manufacturing, multiple dies can be formed simultaneously from a single workpiece, such as a wafer of semiconductor material. Accordingly, techniques for forming and processing semiconductor dies in wafer form are geared towards benefit from improved wafer uniformity (e.g., in thickness, planarity, and precise geometry) for improved compatibility with wafer handling tools (e.g., vacuum chucks and perimeter clamping tools).

### BRIEF DESCRIPTION OF THE DRAWINGS

FIGS. 1 and 2 are simplified schematic cross-sectional views of an example semiconductor device wafer in accordance with various embodiments of the present technology.

FIG. 3 is a simplified schematic planar view of an example semiconductor device wafer in accordance with various embodiments of the present technology.

FIG. 4 is a simplified schematic cross-sectional view of an example semiconductor device in accordance with various embodiments of the present technology.

FIGS. 5 and 6 are simplified schematic cross-sectional views of an example semiconductor device wafer in accordance with various embodiments of the present technology.

FIG. 7 is a flow chart illustrating a method of modifying the geometry of a wafer in accordance with various embodiments of the present technology.

### DETAILED DESCRIPTION

During the manufacture of semiconductor device assemblies, semiconductor wafers are subject to a variety of additive and subtractive processes using a variety of materials to achieve the complex structure required to implement desired circuit functionality. As wafers progress through the manufacturing process, they frequently are moved from one tool or station to another, and accordingly are designed with standard sizes and geometries to facilitate their handling by special tools. One such tool used to manipulate a wafer is a vacuum chuck, which exploits the planarity of a wafer's major surface to provide a mechanically robust connection between the wafer and a movable arm, by applying a vacuum to the planar surface of the wafer (e.g., by pumping a gaseous medium out from between the vacuum chuck and the wafer surface). For wafers that have been subjected to processing steps that reduces their planarity (e.g., for wafers with waviness, or recesses, or other surface features that would permit the ingression of a gas between the vacuum chuck and the wafer surface more quickly than the applied vacuum could remove sufficient quantities of the gas), it can be different to achieve the robust mechanical connection needed to reliably handle the wafer. One approach to overcoming this challenge involves the subtractive planarization of the wafer (e.g., by polishing or grinding the wafer to remove material until planarity is restored), but for thinner wafers, or wafers where thin structural features are near the major surface, such an approach can be limited in effect, as the removal of too much bulk material or active circuitry can negatively impact the strength or functionality of the wafer before a sufficient level of planarity is achieved.

To address these drawbacks and others, various embodiments of the present application provide approaches for additively restoring or providing planarity to the major surface (e.g., the front or the back) of a wafer via a controllable printing process. By mapping the topography of a wafer (e.g., with any one of a variety of regional thickness measurement techniques well-known to those of skill in the art), an amount of material can be calculated for various regions of the wafer, and a replacement material (e.g., an inkjet-printable polymer or dielectric) provided in the thinner regions to restore the wafer to a level of planarity compatible with a vacuum chuck. Similarly, for embodiments in which other wafer handling tools (e.g., tools that mechanically grasp the edge regions or sidewalls of a wafer), the geometry of a wafer can be adjusted to provide good mechanical interface between the wafer and such tools by printing material in the edge (e.g., bevel) or sidewall regions of the wafer.

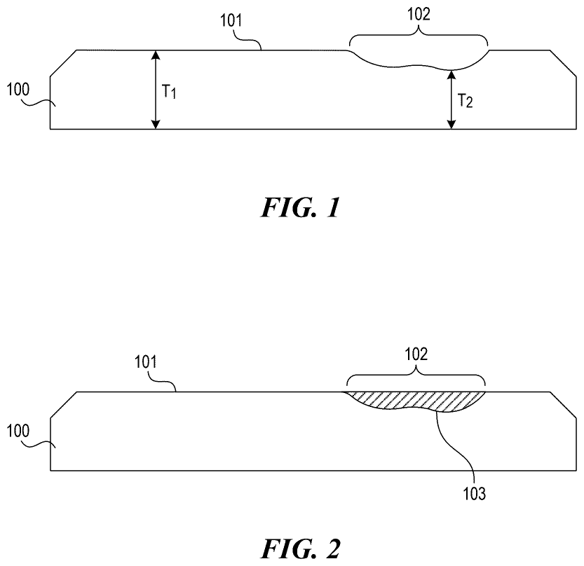

For example, FIG. 1 is a simplified schematic cross-sectional view of an example semiconductor device wafer with a locally irregular geometry that would preclude it from compatibility with a vacuum chuck. As can be seen with reference to FIG. 1, wafer 100 includes a major surface 101 having a region 102 in which the local geometry is irregular (e.g., in which a recess causes the thickness T₂ of the wafer to be less than in other regions where the thickness T₁ is greater). Rather than removing material from the wafer until the thickness of the wafer is everywhere the same, in accordance with an aspect of the present disclosure, a material can be dispensed (e.g., by inkjet printing) at the region 102 to planarize the major surface 101 to a degree compatible with a vacuum chuck.

Rather than a two-step approach of dispensing more additional material than is needed to restore a regular wafer-level geometry, and subsequently subtractively planarizing the major surface 101, embodiments of the present disclosure permit a precise amount of additional material to be added based on a measured local geometry (e.g., a measured variance from planarity at a variety of locations or measurement points on the wafer). In this regard, the wafer topology can be measured by any one of a number of measurement techniques known to those skilled in the art (e.g., optical measurement, interferometry, probe tips, etc.) to build a wafer-level topological map, from which amounts of additional material to be dispensed at different locations on the wafer can be calculated.

After such a calculation, the additional material 103 can be dispensed, as illustrated in FIG. 2 in accordance with one aspect of the present disclosure. As can be seen with reference to FIG. 2, the amount of additional material 103 has been precisely determined and dispensed (e.g., via a printer nozzle) into region 102 based on the calculated volume required to restore major surface 101 to planarity. In accordance with another embodiment, additional material 103 can be dispensed over the entire major surface 101 of the wafer 100, with amounts varying by location as determined by the measurement step to provide planarity across major surface 101. In the present example, however, only region 102 has had additional material 103 dispensed thereon.

The additional material dispensed to additively correct or modify the geometry of a wafer can be any one of a number of materials compatible with an inkjet printing process, including, for example, dielectric materials such as oxides, nitrides, and/or silicides, polyimides, benzocyclobutenes, polybenzoxazoles, acrylates, or even, in some cases, conductive materials such as copper, gold, silver, aluminum and the like.

In some embodiments, subsequent to inkjet printing, the printed material may rapidly dry without an additional heat-treating step. In other embodiments, the printed material may be subjected to a heating step to increase the speed with which the carrier liquid or solvent in the printed material is driven off/evaporated.

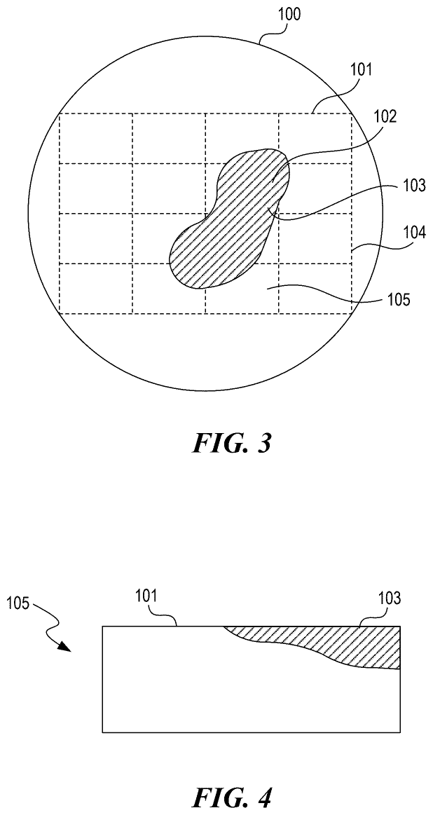

FIG. 3 is a simplified schematic planar view of an example semiconductor device wafer in accordance with various embodiments of the present technology. As can be seen with reference to FIG. 3, the additional material 103 dispensed at region 102 may overlap one or more dies 105, which are divided from one another by scribe lines 104. As a result, in accordance with various embodiments of the present technology, following the singulation of the dies along scribe lines 104, some of the resultant dies 105 may include a portion of the additional material at the major surface 101 thereof, and/or at one or more sidewalls thereof, as illustrated in the simplified schematic cross-sectional view of an example semiconductor device 104 in FIG. 4.

In addition to providing a desired level of planarity of a major surface of a wafer, embodiments of the present disclosure can also provide other desired types of wafer-level geometry. For example, some wafer handling tools are configured to interface with a wafer having a particular bevel geometry at an edge of the major surface thereof (e.g., a bevel angle and/or a bevel size). For wafers that, due to prior processing steps, have regions where the local geometry of the edge bevel varies from the desired geometry, the ability to safely handle the wafer can be comprised. Accordingly, embodiments of the present disclosure can involve restoring a wafer-level edge geometry through additive inkjet printing methods, as described in greater detail below.

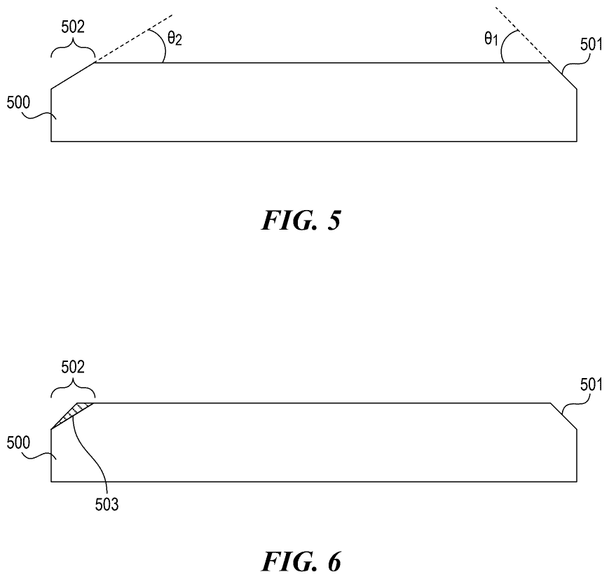

Turning to FIG. 5, a simplified schematic cross-sectional view of an example semiconductor device wafer is provided, in which the wafer has a locally irregular geometry that would preclude it from compatibility with wafer handling tool. As can be seen with reference to FIG. 5, wafer 500 includes a major surface 501 with beveled edges. Wafer 500 includes a region 502 in which the local geometry is irregular (e.g., in which the bevel angle Θ₂ varies from a regular bevel angle Θ₁ elsewhere on the wafer), and that would prevent compatibility with a wafer-handling tool reliant upon the presence of a consistent bevel angle Θ₁ across the wafer 501. To address this issue, in accordance with an aspect of the present disclosure, a material can be dispensed (e.g., by inkjet printing) at the region 502 to restore the desired bevel angle Θ₁ there. To calculate a required amount of additional material, the wafer geometry can be measured by any one of a number of measurement techniques known to those skilled in the art (e.g., optical measurement, interferometry, probe tips, etc.) to build a wafer-level geometry model, from which amounts of additional material to be dispensed at different locations on the wafer can be calculated.

After such a calculation, the additional material 503 can be dispensed, as illustrated in FIG. 6 in accordance with one aspect of the present disclosure. As can be seen with reference to FIG. 6, the amount of additional material 503 has been precisely determined and dispensed (e.g., via a printer nozzle) at region 502 based on the calculated volume required to restore the edge bevel to a consistent angle wafer wide.

Although in the foregoing example embodiments wafer-level geometries have been illustrated and described as relating to planarity of major surfaces or to edge bevel angles and/or sizes, in other embodiments other geometries of a wafer can similarly be modified with an additive printing process, mutatis mutandis.

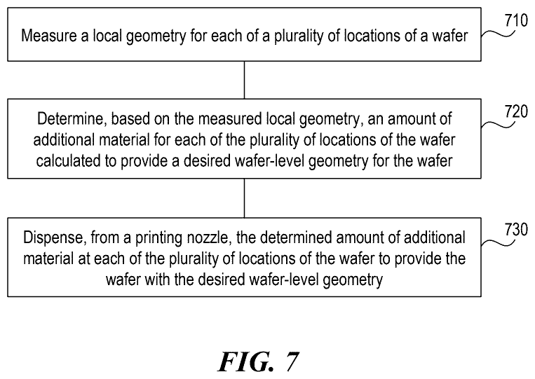

FIG. 7 is a flow chart illustrating a method of altering the geometry of a wafer in accordance with one embodiment of the present disclosure. The method includes measuring a local geometry for each of a plurality of locations of the wafer (box 710). The method further includes determining, based on the measured local geometry, an amount of additional material for each of the plurality of locations of the wafer calculated to provide a desired wafer-level geometry for the wafer (box 720). The method further includes dispensing, from a printing nozzle, the determined amount of additional material at each of the plurality of locations of the wafer to provide the wafer with the desired wafer-level geometry (box 730).

In accordance with one aspect of the present disclosure, the semiconductor devices and wafers illustrated and described with reference to FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In accordance with another aspect of the present disclosure, the semiconductor dies and wafers illustrated and described above could include logic dies (e.g., controller dies, processor dies, etc.), a mix of logic and memory dies (e.g., in a heterogenous reconstituted wafer), transducers (e.g., MEMS devices), communication devices, light emitting devices, or any other solid state/semiconductor device capable of wafer-level formation.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method for planarizing a wafer, the method comprising:
measuring a surface height for each of a plurality of locations of the wafer;
determining, based on the measured surface height, an amount of additional material for each of the plurality of locations of the wafer calculated to provide a desired level of planarity for the wafer; and
dispensing, from a printing nozzle, the determined amount of additional material at each of the plurality of locations of the wafer to planarize the wafer to the desired level of planarity.

2. The method of claim 1, wherein measuring the surface height at one location of the plurality of locations comprises measuring a thickness of the wafer at the one location.

3. The method of claim 1, wherein measuring the surface height at one location of the plurality of locations comprises measuring a distance of a surface of the wafer at the one location from a measuring tool.

4. The method of claim 1, wherein determining the amount of additional material for one location of the plurality of locations comprises calculating a volume of a recess at the one location.

5. The method of claim 1, wherein the printing nozzle is comprised by an inkjet printer.

6. The method of claim 1, wherein the additional material comprises a polymer or a dielectric material.

7. A method for modifying an edge geometry of a wafer, the method comprising:
measuring a local geometry for each of a plurality of edge locations of the wafer;
determining, based on the measured local geometry, an amount of additional material for each of the plurality of edge locations of the wafer calculated to provide a desired edge geometry for the wafer; and
dispensing, from a printing nozzle, the determined amount of additional material at each of the plurality of edge locations of the wafer to provide the wafer with the desired edge geometry.

8. The method of claim 7, wherein measuring the local geometry for one location of the plurality of edge locations comprises measuring a bevel angle at the one location.

9. The method of claim 7, wherein the printing nozzle is comprised by an inkjet printer.

10. The method of claim 7, wherein the additional material comprises a polymer or a dielectric material.

11. A semiconductor device wafer, comprising:
a substrate including a first material having a first major surface surrounded by an edge;
a region at the first major surface with an irregular geometry; and
a second material dispensed in the region to provide the semiconductor device wafer with a wafer-level regular geometry.

12. The semiconductor device wafer of claim 11, wherein the region includes a recess in the first major surface.

13. The semiconductor device wafer of claim 11, wherein the region is at a bevel adjacent the edge.

14. The semiconductor device wafer of claim 11, wherein the second material is different than the first material.

15. The semiconductor device wafer of claim 11, wherein the second material comprises a polymer or a dielectric material.

16. The semiconductor device wafer of claim 11, wherein the irregular geometry is a non-planarity, and the wafer-level regular geometry is planar.

17. The semiconductor device wafer of claim 11, wherein the irregular geometry is a variation in bevel angle, and the wafer-level regular geometry comprises a consistent wafer-level bevel angle.

18. The semiconductor device wafer of claim 11, wherein the irregular geometry is a variation in bevel size, and the wafer-level regular geometry comprises a consistent wafer-level bevel size.
